(19) United States
(12) Patent Application Publication
(10) Pub. No.: US 2018/0197874 A1
(43) Pub. Date: Jul. 12, 2018

(54) SEMICONDUCTOR DEVICE AND METHOD FOR MANUFACTURING SAME

(71) Applicant: Toshiba Memory Corporation, Minato-ku (JP)

(72) Inventors: Yusuke OSHIKI, Kuwana (JP); Masanobu Baba, Yokkaichi (JP)

(73) Assignee: Toshiba Memory Corporation, Minato-ku (JP)

(21) Appl. No.: 15/454,425

(22) Filed: Mar. 9, 2017

Related U.S. Application Data
(60) Provisional application No. 62/444,993, filed on Jan. 11, 2017.

(51) Int. Cl. H01L 27/11556; H01L 27/11519; H01L 27/11548; H01L 27/11565; H01L 27/11575; H01L 27/11582; H01L 23/522; H01L 21/768

(52) U.S. Cl. CPC H01L 27/11556; H01L 27/11519; H01L 27/11548; H01L 27/11565; H01L 21/76877; H01L 27/11582; H01L 23/5226; H01L 21/76837; H01L 21/76816; H01L 27/11575

(57) ABSTRACT

The semiconductor device includes a base material, a plurality of electrode layers, and a first contact portion. The plurality of electrode layers are provided above the base material and arranged along a first direction. The first contact portion extends through the plurality of electrode layers in the first direction. The plurality of electrode layers include a first electrode layer and a second electrode layer. The second electrode layer is positioned between the base material and the first electrode layer. The first contact portion includes a first conductive portion and a first insulating portion. The first conductive portion extends in the first direction, is electrically connected to the first electrode layer, and is insulated from the second electrode layer. The first insulating portion is provided between the base material and the first conductive portion and extends through the second electrode layer in the first direction.

### CROSS-REFERENCE TO RELATED APPLICATIONS

This application is based upon and claims the benefit of priority from U.S. Provisional Patent Application 62/444,993, filed on Jan. 11, 2017; the entire contents of which are incorporated herein by reference.

### FIELD

Embodiments described herein relate generally to a semiconductor device and a method for manufacturing the same.

### BACKGROUND

A semiconductor memory device that has a three-dimensional structure has been proposed in which a memory hole is formed in a stacked body in which multiple electrode layers are stacked, and a charge storage film and a semiconductor film are provided to extend in the stacking direction of the stacked body inside the memory hole. Such a semiconductor memory device includes multiple memory cells connected in series between a drain-side selection transistor and a source-side selection transistor. The electrode layers of the stacked body are used as word lines and selection gates. The stacked body includes a staircase structure portion at an end portion of the stacked body. The staircase structure portion includes multiple terraces provided every electrode layer. The terraces are portions where the electrode layers are drawn out to the outside from the stacked body. It is desirable to reduce the planar size of the staircase structure portion to downscale the semiconductor memory device.

### BRIEF DESCRIPTION OF THE DRAWINGS

FIG. 1 is a plan view showing a planar layout of a semiconductor device according to an embodiment;

FIG. 2 is a perspective view showing a memory cell array of the semiconductor device according to the embodiment;

FIG. 3 is a cross-sectional view showing an example of the columnar portion;

FIG. 4 is a cross-sectional view along line IV-IV in FIG. 3;

FIG. 5 is a plan view showing the memory cell array and a staircase structure portion of the semiconductor device according to the embodiment;

FIG. 6 is a cross-sectional view along line VI-VI in FIG. 5;

FIG. 7 is a cross-sectional view showing an enlargement of a contact portion;

FIG. 8A to FIG. 20B are drawings showing a method for manufacturing the semiconductor device according to the embodiment;

FIG. 21 is a cross-sectional view along line XXI-XXI shown in FIG. 15A;

FIG. 22 is a cross-sectional view along line XXII-XXII shown in FIG. 16A; and

FIG. 23A to FIG. 24B are drawings showing a method for manufacturing the semiconductor device according to the embodiment.

### DETAILED DESCRIPTION

The semiconductor device includes a base material, a plurality of electrode layers, and a first contact portion. The plurality of electrode layers are provided above the base material and arranged along a first direction. The first contact portion extends through the plurality of electrode layers in the first direction. The plurality of electrode layers include a first electrode layer and a second electrode layer. The second electrode layer is positioned between the base material and the first electrode layer. The first contact portion includes a first conductive portion and a first insulating portion. The first conductive portion extends in the first direction, is electrically connected to the first electrode layer, and is insulated from the second electrode layer. A lower end of the first conductive portion is positioned lower than an upper surface of the first electrode layer. The first insulating portion is provided between the base material and the first conductive portion and extends through the second electrode layer in the first direction.

Embodiments will now be described with reference to the drawings. The same components in the drawings are marked with the same reference numerals. The semiconductor device according to the embodiment is a semiconductor memory device including a memory cell array.

<Semiconductor Device>

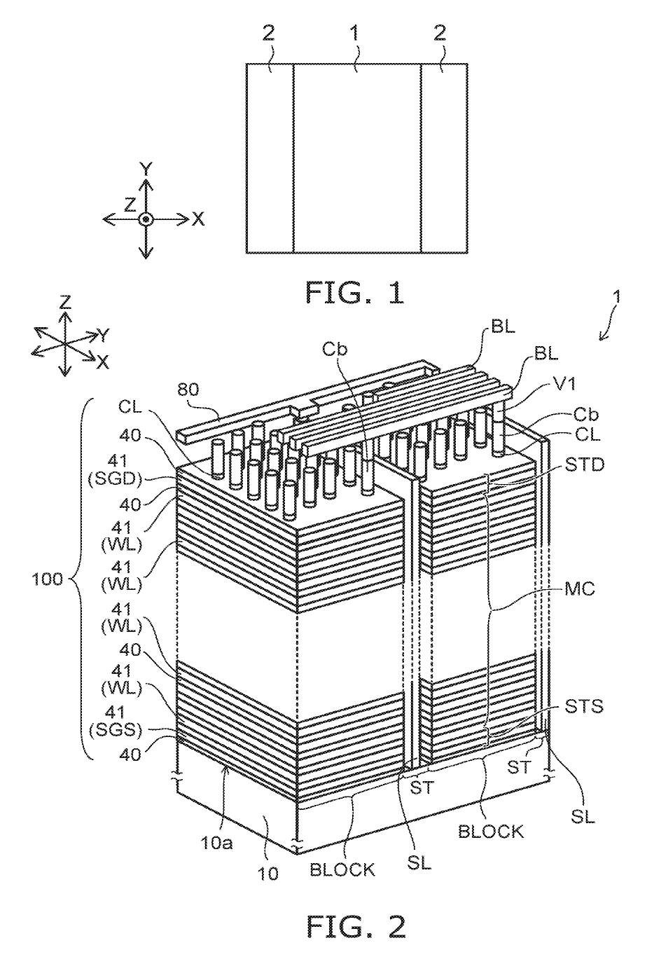

FIG. 1 is a plan view showing a planar layout of a semiconductor device according to the embodiment.

The semiconductor device according to the embodiment includes a memory cell array 1 and a staircase structure portion 2. The memory cell array 1 and the staircase structure portion 2 are provided on a base material. The staircase structure portion 2 is provided on the outer side of the memory cell array 1. In FIG. 1, two mutually-orthogonal directions parallel to a major surface of the base material are taken as an X-direction and a Y-direction; and a direction orthogonal to both the X-direction and the Y-direction is taken as a Z-direction.

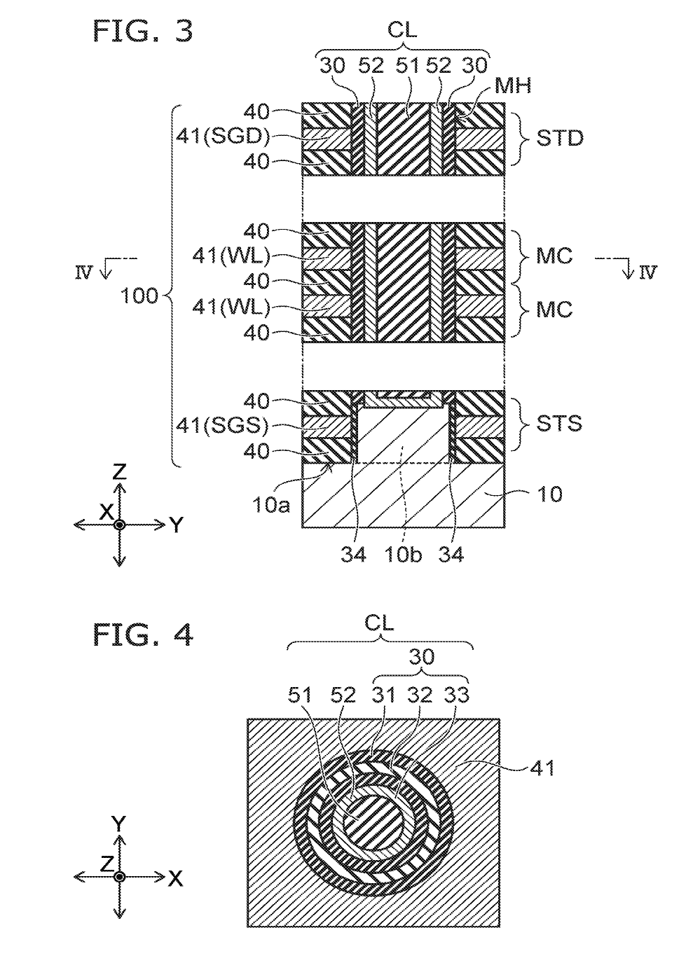

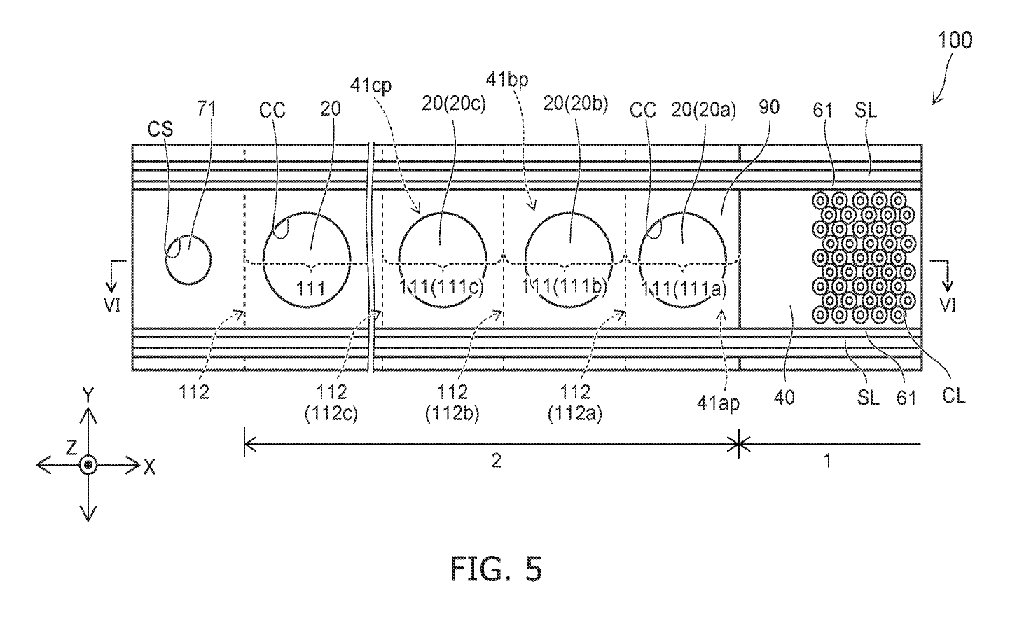

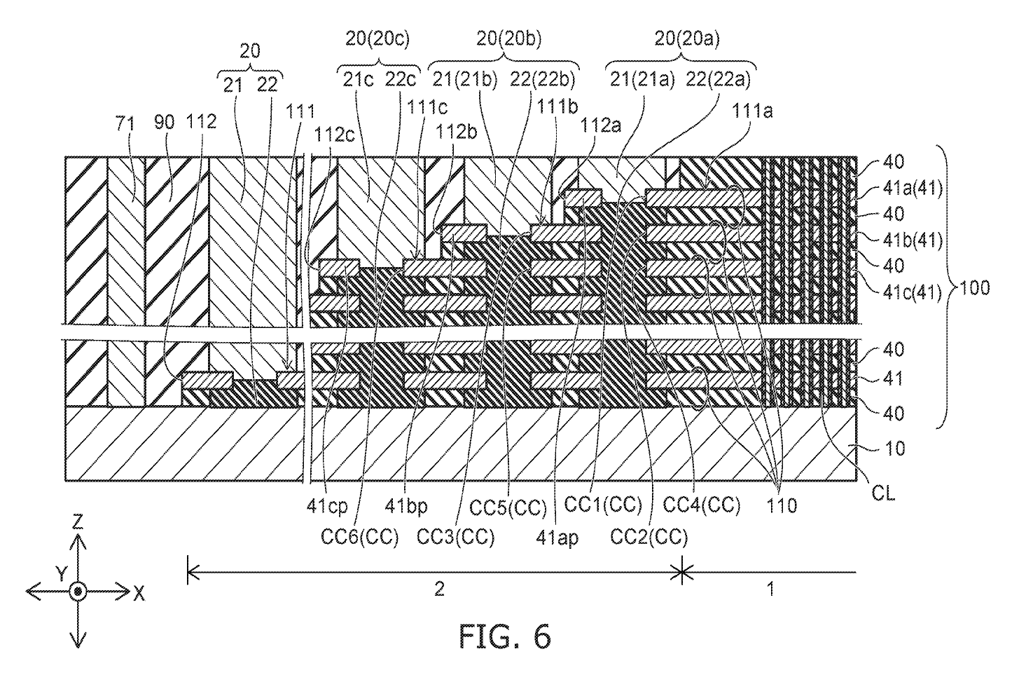

FIG. 2 is a perspective view showing the memory cell array 1 of the semiconductor device according to the embodiment. FIG. 3 and FIG. 4 are cross-sectional views showing an example of the columnar portion. FIG. 4 is a cross-sectional view along line IV-IV in FIG. 3. FIG. 5 is a plan view showing the memory cell array 1 and the staircase structure portion 2 of the semiconductor device according to the embodiment. FIG. 6 is a cross-sectional view along line VI-VI in FIG. 5.

As shown in FIG. 2, the memory cell array 1 includes a stacked body 100, multiple columnar portions CL, and multiple separation portions ST. The stacked body 100 includes multiple electrode layers 41 arranged along the Z-direction. The number of the multiple electrode layers 41 arranged along the Z-direction is arbitrary. For example, the multiple electrode layers 41 include one or more drain-side selection gates SGD, multiple word lines WL, and one or more source-side selection gates SGS.

The source-side selection gate (the lower gate layer) SGS is provided above a base material 10. The base material 10 is, for example, a semiconductor substrate. The semiconductor substrate includes, for example, silicon. The multiple word lines WL are provided above the source-side selection gate SGS. The drain-side selection gate (the upper gate layer) SGD is provided above the multiple word lines WL.

The electrode layers 41 (SGD, WL, and SGS) are stacked above the base material 10 to be separated from each other with insulating bodies 40 interposed. The insulating bodies 40 may be an insulator such as silicon oxide, etc., or may be an air gap.

The selection gate SGD is used as a gate electrode of a drain-side selection transistor STD. The selection gate SGS is used as a gate electrode of a source-side selection transistor STS. Multiple memory cells MC are connected in series between the drain-side selection transistor STD and the source-side selection transistor STS. The word lines WL are used as gate electrodes of the memory cells MC. The drain-side selection transistor STD, the multiple memory cells MC, and the source-side selection transistor STS that are arranged in the Z-direction in the stacked body 100 are connected in series via the semiconductor body 52 of the columnar portion CL described below and are included in one memory string. For example, the memory strings have a staggered arrangement in a planar direction parallel to the XY plane; and the multiple memory cells MC are provided three-dimensionally in the X-direction, the Y-direction, and the Z-direction.

The separation portions ST are provided inside the stacked body 100. The separation portions ST extend through the stacked body 100 in the stacking direction (the Z-direction) and the X-direction. The separation portions ST divide the stacked body 100 into a plurality in the Y-direction. The regions that are divided by the separation portions ST are called “blocks.”

A source layer SL is disposed inside the separation portion ST. For example, the source layer SL spreads in a plate configuration in the Z-direction and the X-direction. As shown in FIG. 5, an insulating film 61 is provided between the source layer SL and the stacked body 100. The source layer SL and the electrode layers 41 (referring to FIG. 2) are insulated from each other by the insulating film 61. As shown in FIG. 2, an upper layer interconnect 80 that extends in the Y-direction is disposed above the source layer SL. The upper layer interconnect 80 is electrically connected to the multiple source layers SL arranged along the Y-direction.

The columnar portions CL are provided inside the stacked body 100 divided by the separation portions ST. The columnar portions CL extend in the Z-direction. For example, the columnar portions CL are arranged in a staggered lattice configuration or a square lattice configuration inside the memory cell array 1. The drain-side selection transistor STD, the multiple memory cells MC, and the source-side selection transistor STS are formed for the columnar portion CL. For example, the columnar portion CL is formed in a circular columnar configuration or an elliptical columnar configuration.

As shown in FIG. 3, the columnar portion CL includes, for example, a core portion 51, a semiconductor body 52, and a memory portion 30. The configuration of the core portion 51 is a columnar configuration extending in the Z-direction. For example, the core portion 51 is made of an insulating material such as silicon oxide, etc. The semiconductor body 52 is provided between the core portion 51 and the electrode layers 41. The configuration of the semiconductor body 52 is, for example, a tubular configuration in which the lower end is plugged. The memory portion 30 is provided between the semiconductor body 52 and the electrode layers 41. The memory portion 30 that is between the drain-side selection gate SGD and the semiconductor body 52 may be removed. In such a case, an insulating film is provided instead of the memory portion 30.

As shown in FIG. 4, the memory portion 30 includes a blocking insulating film 31, a charge storage portion 32, and a tunneling insulating film 33. The charge storage portion 32 includes, for example, at least one of a floating gate or trap sites that trap charge. The threshold voltage of the memory cell MC changes due to the existence or absence of the charge or the amount of the charge inside the charge storage portion 32. Thereby, the memory cell MC stores information.

The tunneling insulating film 33 is provided between the semiconductor body 52 and the charge storage portion 32. Tunneling of charge, e.g., electrons and/or holes, occurs in the tunneling insulating film 33 when erasing the information and when programming the information.

The blocking insulating film 31 is provided between the charge storage portion 32 and the stacked body 100. For example, the blocking insulating film 31 suppresses back-tunneling of the charge in the erase operation from the word line WL into the charge storage portion 32 included in the memory portion 30.

As shown in FIG. 3, a semiconductor pillar 10b may be provided between the columnar portion CL and the base material 10. For example, the semiconductor body 52 is electrically connected to the base material 10 via the semiconductor pillar 10b. A gate insulating film 34 is provided between the semiconductor pillar 10b and the stacked body 100. For example, the semiconductor pillar 10b opposes, with the gate insulating film 34 interposed, the source-side selection gate SGS in a direction orthogonal to the Z-direction.

The semiconductor pillar 10b may be omitted. In the case where the semiconductor pillar 10b is omitted, for example, the columnar portion CL is connected directly to the base material 10.

As shown in FIG. 2, multiple bit lines BL that extend in the Y-direction are arranged above the upper end portions of the columnar portions CL. The upper end portion of the columnar portion CL is electrically connected to one of the bit lines BL via a plug Cb and a plug V1. One bit line BL is electrically connected to one columnar portion CL selected from each block.

As shown in FIG. 5 and FIG. 6, the stacked body 100 includes the staircase structure portion 2. As shown in FIG. 6, the stacked body 100 includes multiple structure bodies 110. In the staircase structure portion 2, the end portions of the structure bodies 110 are arranged in a staircase configuration. The structure body 110 includes the electrode layer 41 and the insulating body 40.

In the staircase structure portion 2 as shown in FIG. 5 and FIG. 6, the portions where the upper surfaces of the structure bodies 110 are exposed are called “terraces 111.” In the staircase structure portion 2, the portions where the side surfaces of the structure bodies 110 are exposed are called “level differences 112.”

In the stacked body 100, a hole CC is formed every terrace 111. The hole CC extends through the stacked body 100 in the Z-direction.

An insulating film 90 is provided on the stacked body 100 of the staircase structure portion 2 and on the base material 10 on the outer side of the stacked body 100. The position in the Z-direction of the upper surface of the insulating film 90 is substantially the same as the position in the Z-direction of the upper surface of the stacked body 100 in the memory cell array 1.

Multiple contact portions 20 are provided in the staircase structure portion 2. The contact portions 20 extend through the insulating film 90 and through the stacked body 100 in the Z-direction. A portion of the contact portions 20 is provided inside the holes CC.

The contact portion 20 includes a conductive portion 21 and an insulating portion 22. The conductive portion 21 extends through the insulating film 90 in the Z-direction and contacts the terrace 111. The insulating portion 22 is provided between the base material 10 and the conductive portion 21 and extends through the stacked body 100 in the Z-direction. The insulating portion 22 is provided inside the hole CC. A portion of the conductive portion 21 overlaps the hole CC when viewed from the Z-direction. For example, the conductive portions 21 are connected one-to-one to the electrode layers 41. The conductive portion 21 may be connected to the side surface of the hole CC of the respective electrode layer 41 in addition to the upper surface (the terrace 111) of the respective electrode layer 41. In other words, the upper portion of the contact portion 20 includes the conductive portion 21; and the lower portion includes the insulating portion 22. The position of the interface between the conductive portion 21 and the insulating portion 22 in the Z-direction is positioned between the upper surface and the lower surface of the electrode layer 41 of the uppermost layer of the multiple electrode layers 41 pierced by the contact portion 20. For the multiple electrode layers 41 pierced by the contact portion 20, the position of the interface between the conductive portion 21 and the insulating portion 22 in the Z-direction may be positioned between the lower surface of the electrode layer 41 of the uppermost layer and the upper surface of the electrode layer 41 of one layer below the electrode layer 41 of the uppermost layer.

The multiple electrode layers 41 include, for example, a first electrode layer 41a, a second electrode layer 41b, and a third electrode layer 41c. The first electrode layer 41a is provided above the base material 10. The second electrode layer 41b is provided between the first electrode layer 41a and the base material 10. The third electrode layer 41c is provided between the second electrode layer 41b and the base material 10.

The region of the first electrode layer 41a where the insulating body 40 is not provided above the region is taken as a first terrace 111a (the terrace 111). The region of the second electrode layer 41b not overlapping the first electrode layer 41a when viewed from the Z-direction where the insulating body 40 is not provided above the region is taken as a second terrace 111b (the terrace 111). The region of the third electrode layer 41c not overlapping the second electrode layer 41b when viewed from the Z-direction where the insulating body 40 is not provided above the region is taken as a third terrace 111c (the terrace 111).

The positional relationship between the electrode layers 41 and the holes CC will now be described. In the description hereinbelow, the portion of some hole CC piercing some electrode layer 41 is taken as the “hole CCn.” n is any integer.

The first electrode layer 41a includes a first end portion 41ap. The upper surface of the first end portion 41ap corresponds to the first terrace 111a. A first hole CC1 is formed in the first end portion 41ap.

The second electrode layer 41b includes a second end portion 41bp. The upper surface of the second end portion 41bp corresponds to the second terrace 111b. A second hole CC2 and a third hole CC3 are formed in the second electrode layer 41b. At least a portion of the second hole CC2 overlaps the first hole CC1 when viewed from the Z-direction. The third hole CC3 is disposed in the second end portion 41bp.

The third electrode layer 41c includes a third end portion 41cp. The upper surface of the third end portion 41cp corresponds to the third terrace 111c. A fourth hole CC4, a fifth hole CC5, and a sixth hole CC6 are formed in the third electrode layer 41c. At least a portion of the fourth hole CC4 overlaps the first hole CC1 and the second hole CC2 when viewed from the Z-direction. In other words, the first hole CC1, the second hole CC2, and the fourth hole CC4 are mutually-different portions of the same hole CC. At least a portion of the fifth hole CC5 overlaps the third hole CC3 in the Z-direction. The sixth hole CC6 is disposed in the third end portion 41cp.

The multiple contact portions 20 include, for example, a first contact portion 20a, a second contact portion 20b, and a third contact portion 20c.

The first contact portion 20a includes a first conductive portion 21a and a first insulating portion 22a. The first conductive portion 21a extends through the insulating film 90 along the Z-direction and is connected to the first electrode layer 41a at the first terrace 111a. A portion of the first conductive portion 21a overlaps the first hole CC1, the second hole CC2, and the fourth hole CC4 when viewed from the Z-direction. Another portion of the first conductive portion 21a surrounds the first hole CC1 and contacts the upper surface of the first electrode layer 41a in a region having, for example, an annular configuration. The first conductive portion 21a also contacts the inner surface of the first hole CC1 and may be connected to the first electrode layer 41a at the inner surface as well. The lower end of the first conductive portion 21a is positioned lower than the upper surface of the first electrode layer 41a, and is positioned higher than the upper surface of the second electrode layer 41b. The first insulating portion 22a is provided between the first conductive portion 21a and the base material 10. The first insulating portion 22a extends in the Z-direction and reaches the upper surface of the base material 10 via the first hole CC1, the second hole CC2, and the fourth hole CC4.

The second contact portion 20b includes a second conductive portion 21b and a second insulating portion 22b. The second conductive portion 21b extends through the insulating film 90 along the Z-direction and is connected to the second electrode layer 41b at the second terrace 111b. A portion of the second conductive portion 21b overlaps the third hole CC3 and the fifth hole CC5 when viewed from the Z-direction. Another portion of the second conductive portion 21b surrounds the third hole CC3 and contacts the upper surface of the second electrode layer 41b in a region having, for example, an annular configuration. The second conductive portion 21b also contacts the inner surface of the third hole CC3 and may be connected to the second electrode layer 41b at the inner surface as well. The lower end of the second conductive portion 21b is positioned lower than the upper surface of the second electrode layer 41b, and is positioned higher than the upper surface of the third electrode layer 41c. The second insulating portion 22b is provided between the second conductive portion 21b and the base material 10. The second insulating portion 22b extends in the Z-direction and reaches the upper surface of the base material 10 via the third hole CC3 and the fifth hole CC5.

The third contact portion 20c includes a third conductive portion 21c and a third insulating portion 22c. The third conductive portion 21c extends through the insulating film 90 along the Z-direction and is connected to the third electrode layer 41c at the third terrace 111c. A portion of the third conductive portion 21c overlaps the sixth hole CC6 when viewed from the Z-direction. Another portion of the third conductive portion 21c surrounds the sixth hole CC6 and contacts the upper surface of the third electrode layer 41c in a region having, for example, an annular configuration. The third conductive portion 21c also contacts the inner surface of the sixth hole CC6 and may be connected to the third electrode layer 41c at the inner surface of the sixth hole CC6 as well. The third insulating portion 22c is provided between the third conductive portion 21c and the base material 10. The third insulating portion 22c extends in the Z-direction and reaches the upper surface of the base material 10 via the sixth hole CC6.

The first end portion 41ap has a first level difference 112a. The first level difference 112a is positioned between the first contact portion 20a and the second contact portion 20b in the X-direction. The second end portion 41bp has a second level difference 112b. The second level difference 112b is positioned between the second contact portion 20b and the third contact portion 20c in the X-direction. The third end portion 41cp has a third level difference 112c. The third contact portion 20c is positioned between the second level difference 112b and the third level difference 112c.

A contact plug 71 that extends through the insulating film 90 in the Z-direction is provided on the outer side of the stacked body 100. For example, the contact plug 71 is connected to the base material 10.

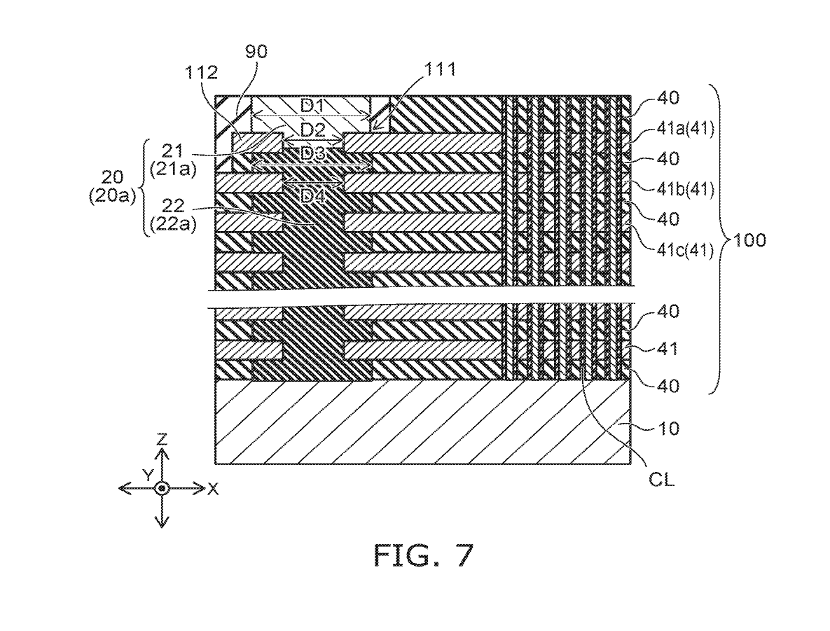

FIG. 7 is a cross-sectional view showing an enlargement of the contact portion 20.

As shown in FIG. 7, a diameter D1 of the conductive portion 21 positioned inside the insulating film 90 is larger than a diameter D2 of the conductive portion 21 positioned inside the electrode layer 41. In other words, D1>D2. For example, the diameter D1 is larger than a diameter that is 2 times the diameter D2. In other words, D1>(2×D2).

A diameter D3 of the insulating portion 22 positioned inside the insulating body 40 is larger than a diameter D4 of the insulating portion 22 positioned inside the electrode layer 41. In other words, D3>D4.

<Manufacturing Method>

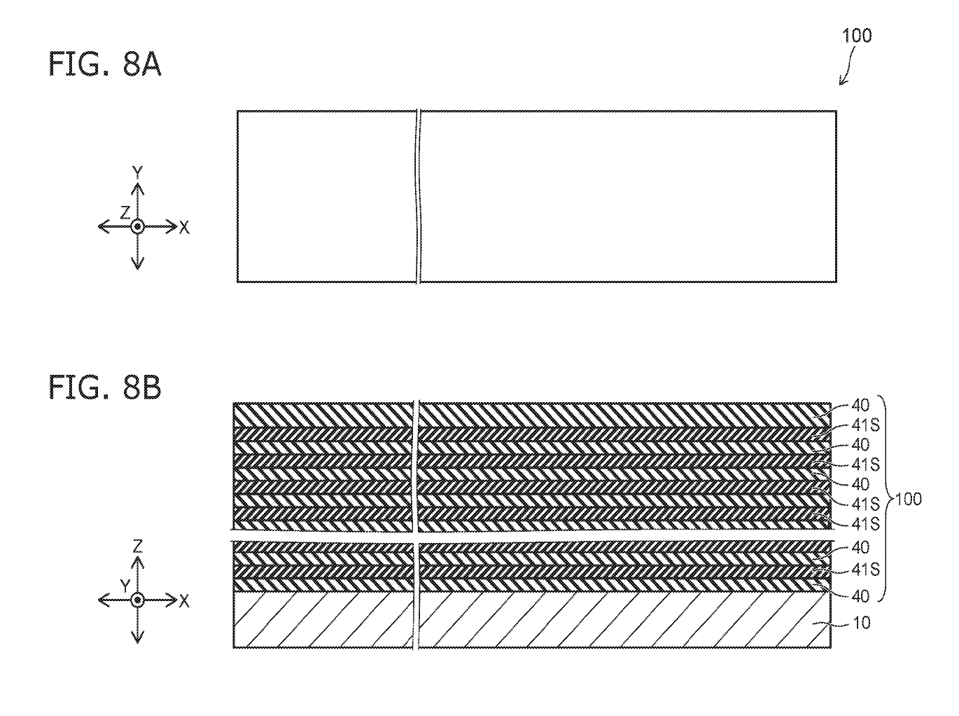

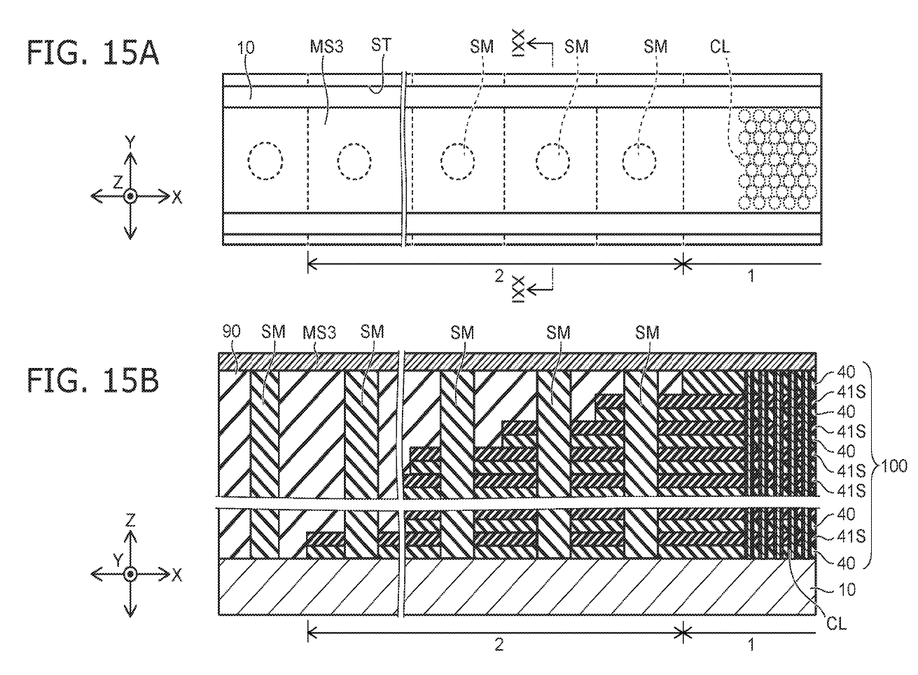

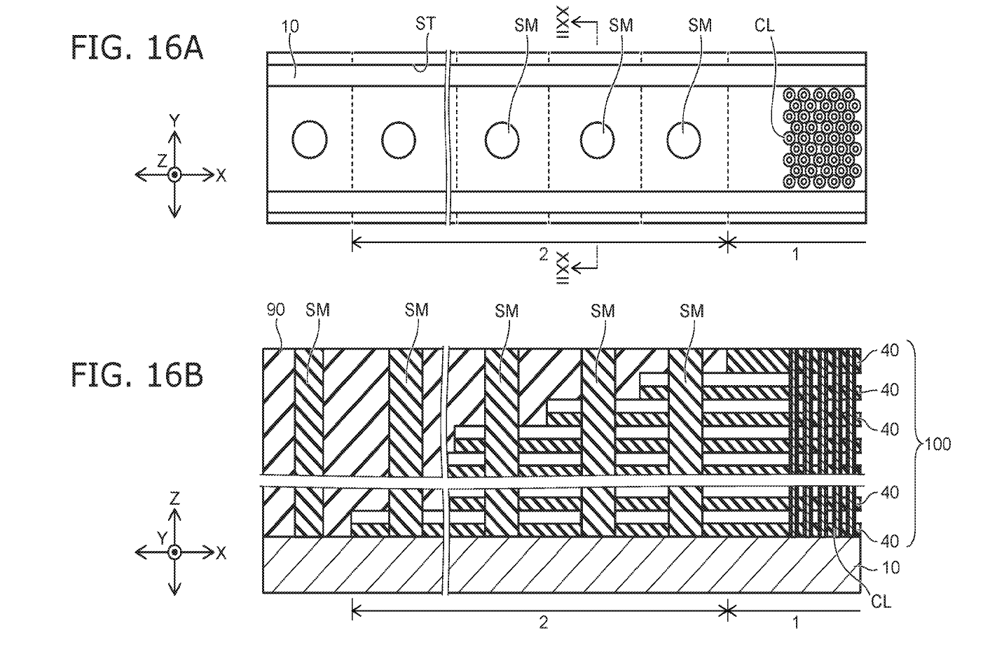

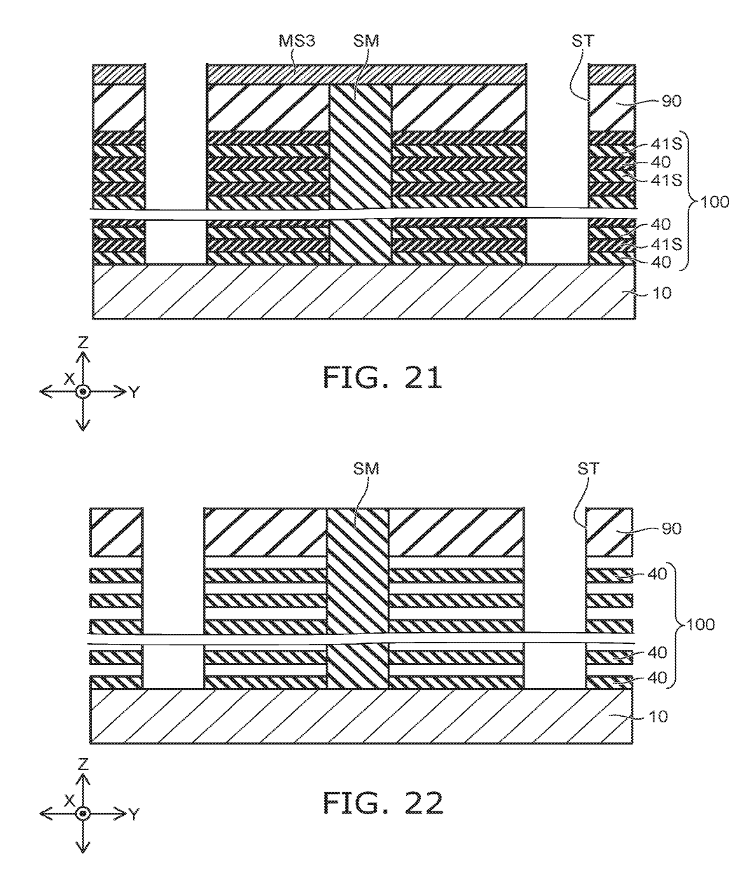

FIG. 8A to FIG. 20B are drawings showing the method for manufacturing the semiconductor device according to the embodiment. FIG. 21 is a cross-sectional view along line XXI-XXI shown in FIG. 15A. FIG. 22 is a cross-sectional view along line XXII-XXII shown in FIG. 16A.

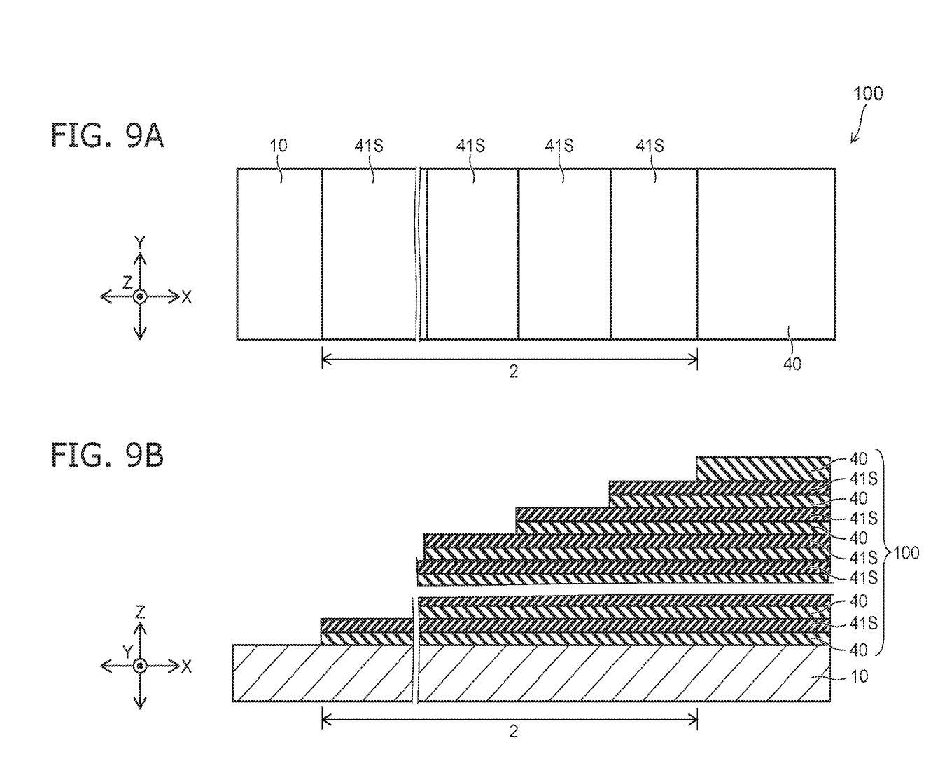

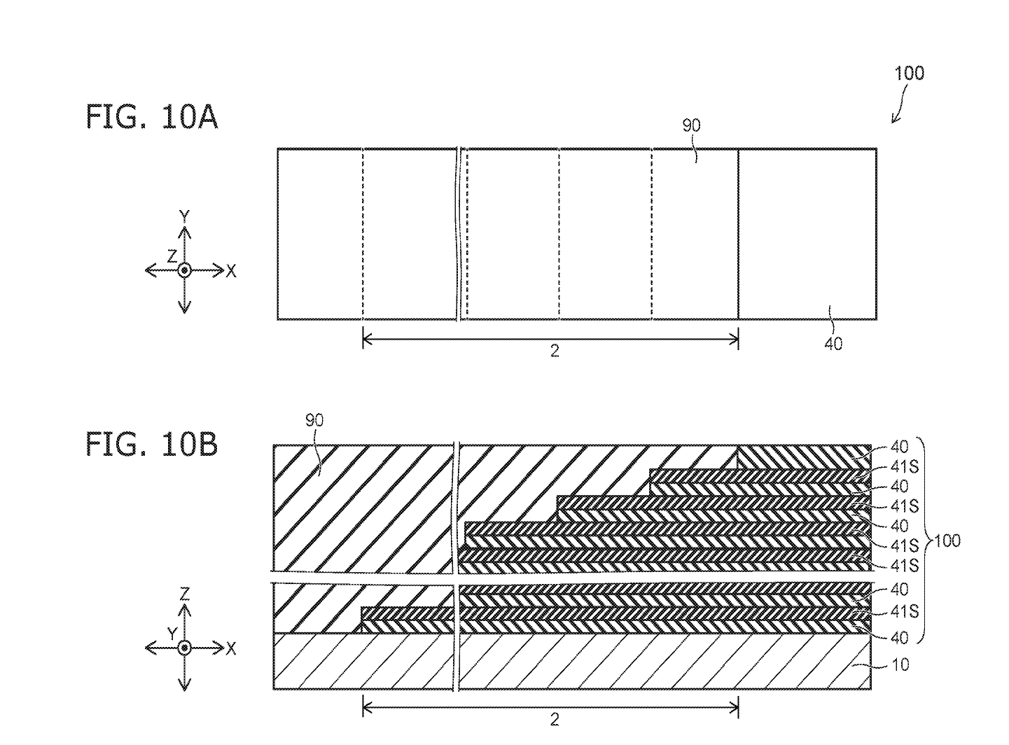

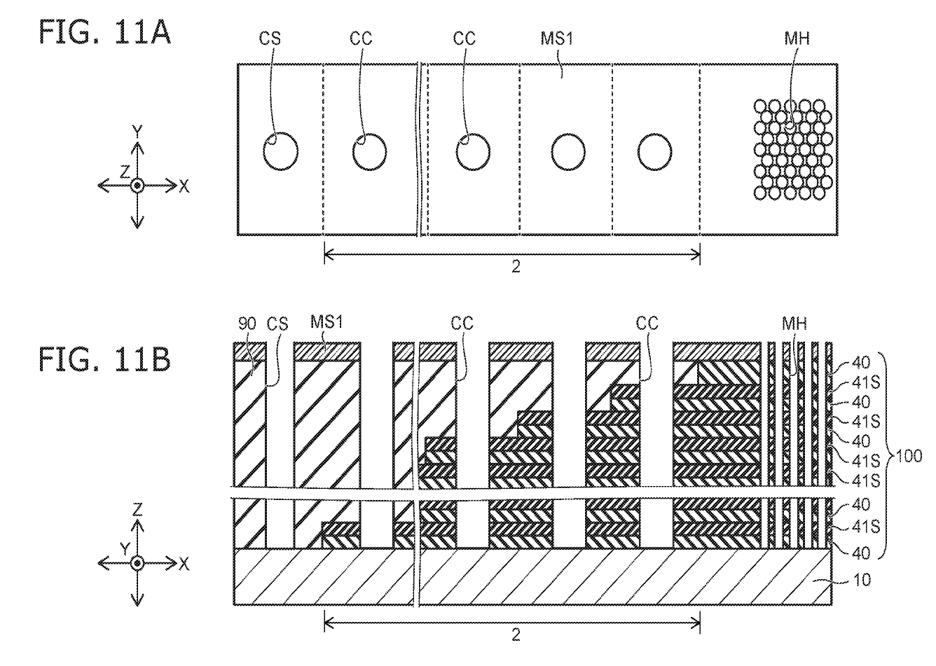

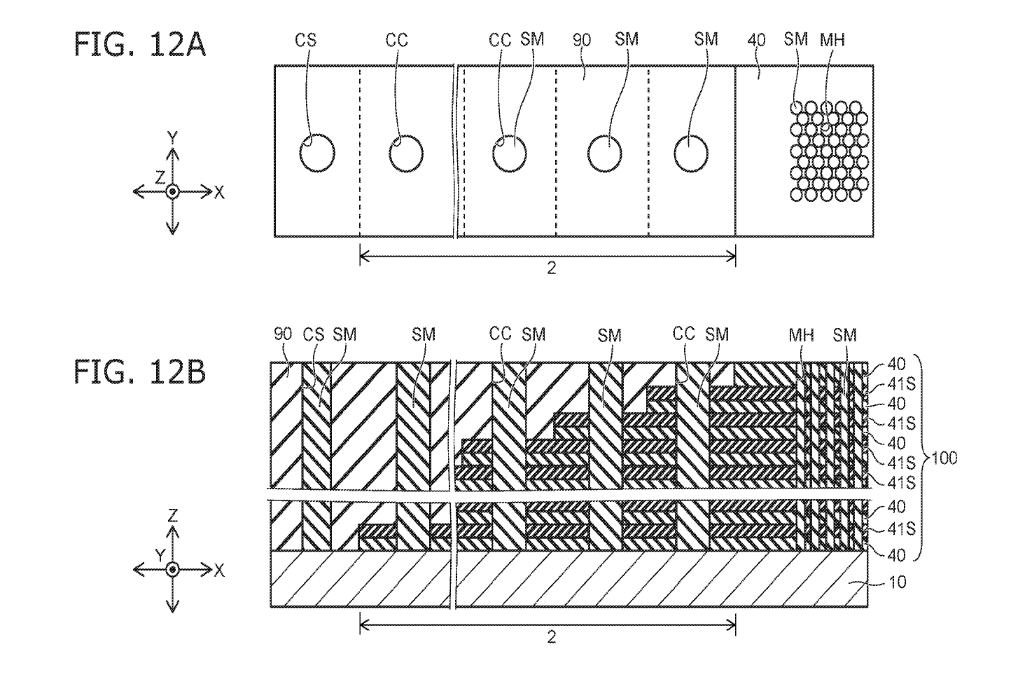

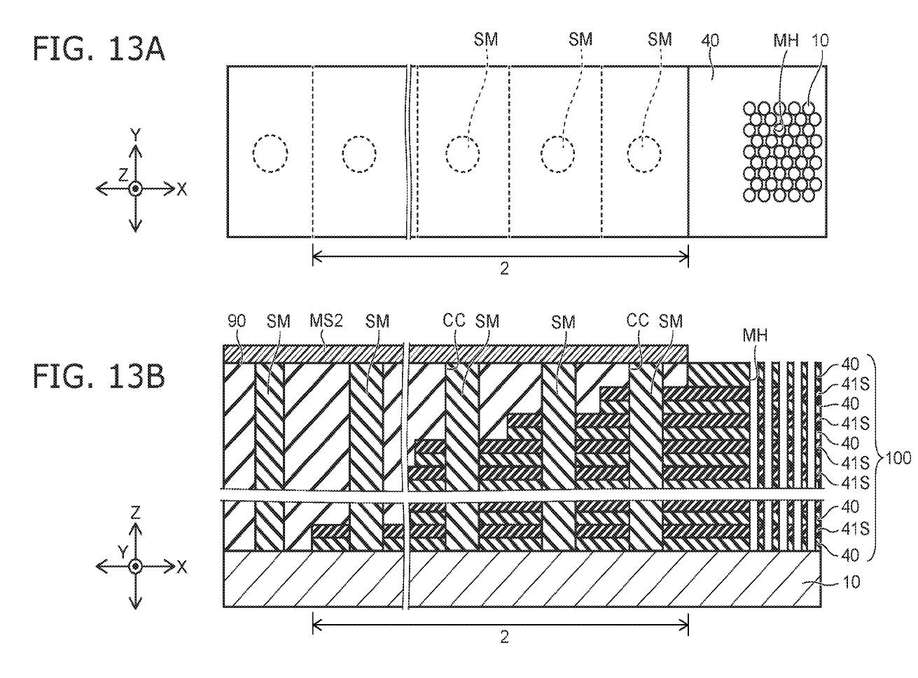

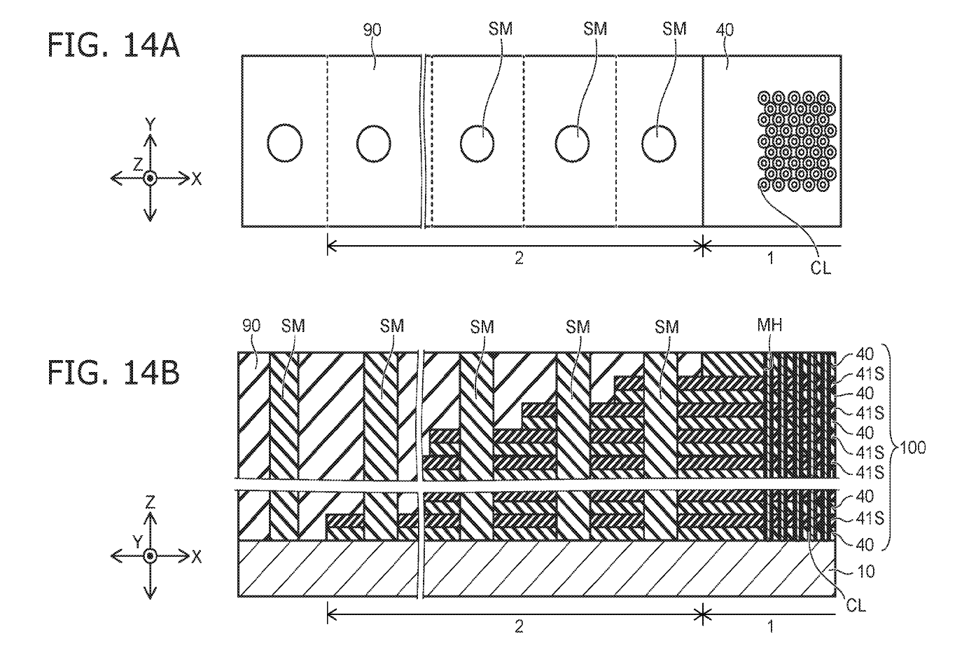

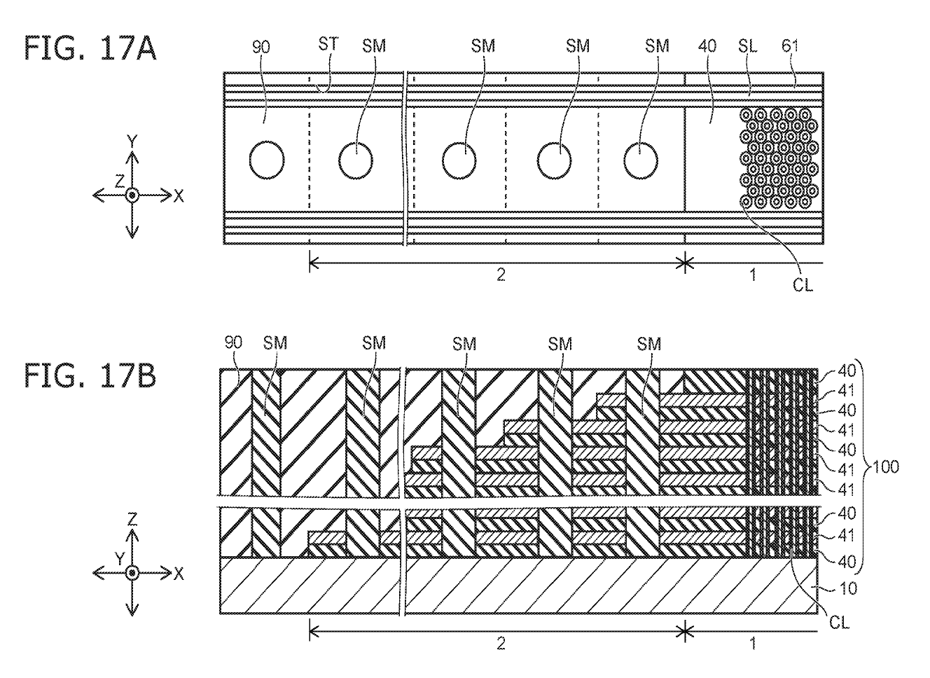

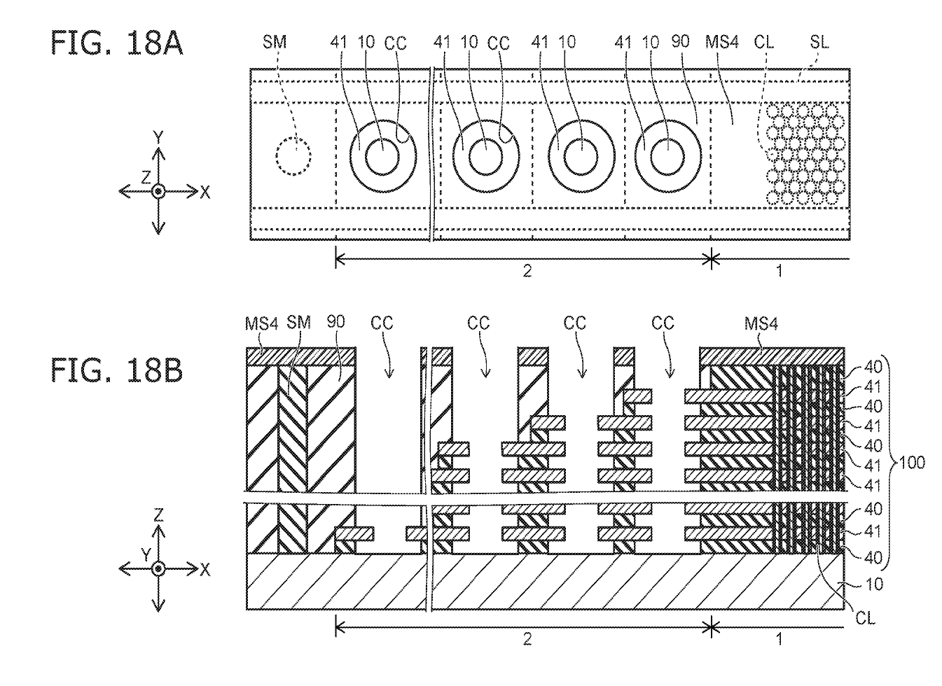

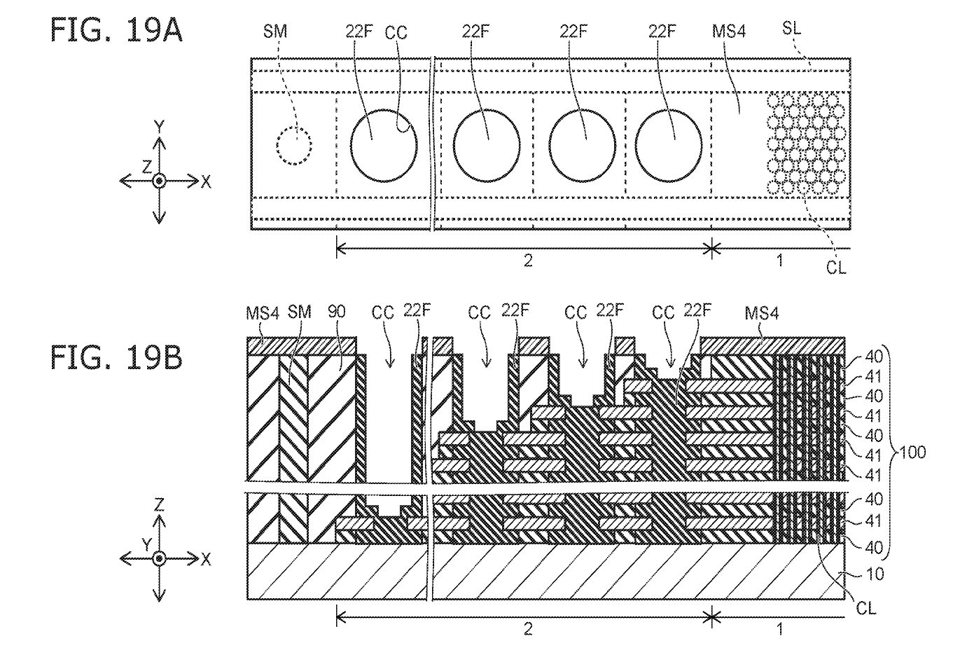

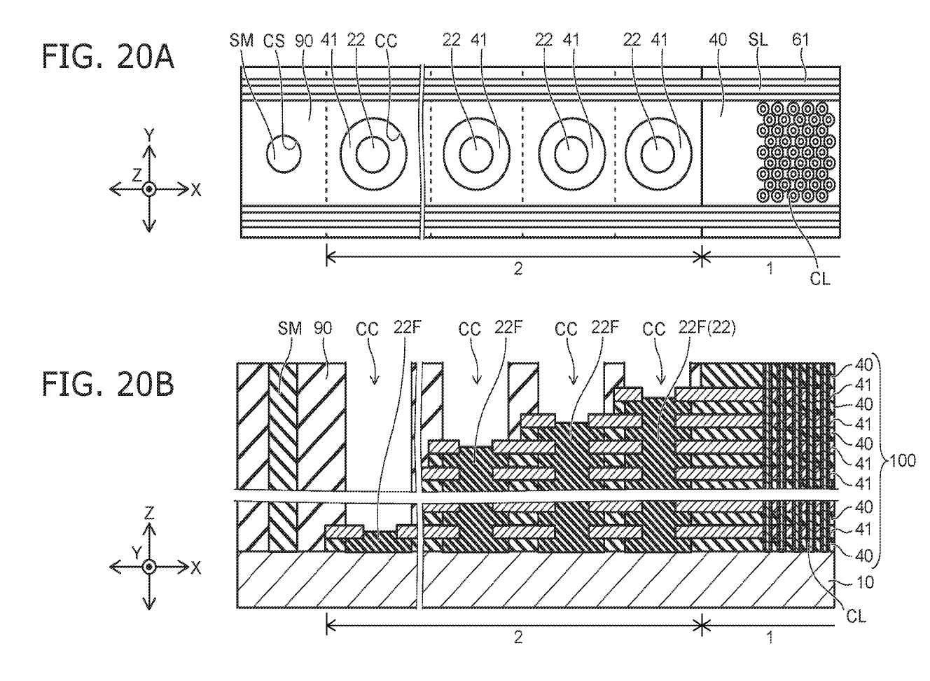

FIG. 8A, FIG. 9A, FIG. 10A, FIG. 11A, FIG. 12A, FIG. 13A, FIG. 14A, FIG. 15A, FIG. 16A, FIG. 17A, FIG. 18A, FIG. 19A, and FIG. 20A correspond to the plan view shown in FIG. 5. FIG. 8B, FIG. 9B, FIG. 10B, FIG. 11B, FIG. 12B, FIG. 13B, FIG. 14B, FIG. 15B, FIG. 16B, FIG. 17B, FIG. 18B, FIG. 19B, and FIG. 20B correspond to the cross-sectional view shown in FIG. 6.

<1. Formation of the Stacked Body 100>

As shown in FIG. 8A and FIG. 8B, the stacked body 100 is formed on the base material 10. For example, the stacked body 100 is formed by stacking a sacrificial layer 41S as a first layer and the insulating body 40 as a second layer alternately in the Z-direction. The insulating body 40 and the sacrificial layer 41S are formed using materials that can have selectivity with respect to each other for the etching. In the case where, for example, silicon oxide is selected as the insulating body 40, for example, silicon nitride is selected as the sacrificial layer 415.

<2. Formation of the Staircase Structure Portion 2>

As shown in FIG. 9A and FIG. 9B, the end portion of the stacked body 100 is patterned into a staircase configuration. Thereby, the staircase structure portion 2 is formed in the stacked body 100. For example, the staircase structure portion 2 is formed using a well-known method such as “resist slimming,” etc.

Subsequently, as shown in FIG. 10A and FIG. 10B, the insulating film 90 is formed on the base material 10 and on the staircase structure portion 2. The insulating film 90 is formed to bury the staircase structure portion 2. For example, planarization such as CMP (chemical mechanical polishing) or the like is performed for the upper surface of the stacked body 100 and the upper surface of the insulating film 90. Thereby, the upper surface of the uppermost layer of the stacked body 100 and the upper surface of the insulating film 90 are in substantially the same plane.

<3. Formation of the Holes CC>

As shown in FIG. 11A and FIG. 11B, the holes CC, a hole CS, and memory holes MH are formed in the stacked body 100.

The holes CC pierce the insulating film 90 and the staircase structure portion 2 and reach the base material 10. The hole CS is formed on the outer side of the stacked body 100. The hole CS pierces the insulating film 90 and reaches the base material 10. The memory holes MH are formed in a region used to form the memory cell array 1 in subsequent processes. For example, a mask material MS1 is formed on the stacked body 100 and on the insulating film 90. For example, a resin layer is formed on the stacked body 100 and on the insulating film 90; and subsequently, a hole pattern is formed in the resin layer by photolithography. Thereby, the mask material MS1 is formed. Anisotropic etching of the stacked body 100 and the insulating film 90 is performed using the mask material MS1. Thereby, the holes CC and the memory holes MH are formed in the stacked body 100; and the hole CS is formed in the insulating film 90 on the outer side of the stacked body 100. Subsequently, the mask material MS1 that remains is removed.

<4. Formation of the Sacrificial Member SM>

As shown in FIG. 12A and FIG. 12B, the sacrificial member SM is formed inside the memory holes MH, inside the holes CC, and inside the hole CS. For example, the sacrificial member SM is formed of a material that can have selectivity with respect to the sacrificial layers 41S in the etching. For example, the sacrificial member SM is formed using amorphous silicon.

In the case where the insulating bodies 40 are set to be air gaps, the second layers (the layers including, for example, silicon oxide) are removed in a subsequent process. In such a case, the sacrificial member SM is formed of a material that can have etching selectivity with respect to the first layers and the second layers. For example, the sacrificial member SM is formed of a material including aluminum oxide.

<5. Formation of the Columnar Portions CL>

As shown in FIG. 13A and FIG. 13B, a mask material MS2 is formed on the hole CS, on the holes CC, and on the insulating film 90. At this time, the sacrificial member SM that is provided inside the memory holes MH is not covered with the mask material MS2. For example, the mask material MS2 is formed using photolithography.

The sacrificial member SM that is inside the memory holes MH is removed. At this time, the sacrificial member SM that is provided inside the hole CS and inside the holes CC is covered with the mask material MS2 and therefore is not removed. For example, the sacrificial member SM that is inside the memory holes MH is removed by wet etching using a choline aqueous solution.

After removing the mask material MS2, the columnar portions CL are formed inside the memory holes MH as shown in FIG. 14A and FIG. 14B. For example, the memory portion 30 is formed on the side surfaces of the memory holes MH. Subsequently, the semiconductor body 52 is formed on the side surface of the memory portion 30. Subsequently, the core portion 51 is filled into the interiors of the memory holes MH. Thereby, the columnar portions CL are formed inside the memory holes MH.

<6. Formation of the Separation Portions ST>

As shown in FIG. 15A, FIG. 15B, and FIG. 21, the separation portions ST that divide the stacked body 100 in the Y-direction are formed. A mask material MS3 that has trenches extending in the X-direction is formed on the stacked body 100, on the insulating film 90, on the sacrificial member SM, and on the columnar portions CL. Anisotropic etching is performed using the mask material MS3. Thereby, The separation portions ST are formed in the stacked body 100 and the insulating film 90. Subsequently, the mask material MS3 is removed.

<7. Formation of the Electrode Layers 41>

As shown in FIG. 16A, FIG. 16B, and FIG. 22, a replace process that replaces the sacrificial layers 41S with the electrode layers 41 is implemented. For example, wet etching using hot phosphoric acid is performed via the separation portions ST. Thereby, the sacrificial layers 41S are removed. At this time, for example, the sacrificial member SM that is inside the holes CC function as posts supporting the staircase structure portion 2. Thereby, for example, the collapse of the staircase structure portion 2 is suppressed.

As shown in FIG. 17A and FIG. 17B, the electrode layers 41 are formed by filling a conductive material such as tungsten, etc., into the space made by removing the sacrificial layers 41S. Thereby, the main portions of the memory cell array 1 are formed. The insulating film 61 is formed on the side surface of the separation portion ST. Subsequently, the source layer SL is formed inside the separation portion ST. For example, the source layer SL is connected to the base material 10.

<8. Enlargement of the Holes CC>

As shown in FIG. 18A and FIG. 18B, the sacrificial member SM that is inside the holes CC is removed. For example, a mask material MS4 is formed on the insulating film 90, on the stacked body 100, on the columnar portions CL, on the insulating films 61, and on the source layers SL. The upper surface of the sacrificial member SM formed inside the hole CS is in the state of being covered with the mask material MS4; and the upper surfaces of the sacrificial member SM formed inside the holes CC are exposed from the mask material MS4. Subsequently, for example, anisotropic etching is performed. Thereby, the sacrificial member SM that is inside the holes CC is removed. Subsequently, for example, isotropic etching such as wet etching using hydrofluoric acid or the like is performed. Thereby, the exposed surfaces of the insulating film 90 and the insulating bodies 40 at the inner surfaces of the holes CC are caused to recede. As a result, the diameters of the holes CC inside the insulating film 90 become large. Also, the diameters of the holes CC inside the insulating bodies 40 become large. Thereby, a portion of the upper surfaces of the electrode layers 41 is exposed from the insulating film 90 inside the holes CC. For example, the diameters of the holes CC positioned inside the insulating film 90 are larger than diameters that are 2 times the diameters of the holes CC positioned inside the electrode layers 41.

The diameters of the holes CC may be enlarged by anisotropic etching. In such a case, the diameters of the holes CC inside the insulating film 90 are enlarged. The diameters of the holes CC inside the insulating film 90 become larger than the diameters of the holes CC inside the insulating bodies 40.

<9. Formation of the Contact Portion 20>

As shown in FIG. 19A and FIG. 19B, an insulating film 22F is formed inside the holes CC. The insulating film 22F is formed in a liner configuration on the inner surfaces of the holes CC. At this time, the film thickness of the insulating film 22F is thicker than the value of ½ of the diameters of the holes CC inside the electrode layers 41 and is thinner than the value of ½ of the diameters inside the insulating film 90. By forming the insulating film 22F using such film formation conditions, the portions of the holes CC positioned inside the electrode layers 41 are filled with the insulating film 22F. Thereby, the insulating film 22F is in a state of being filled into the region lower than the electrode layer 41 of the uppermost layer inside the hole CC. On the other hand, the portions of the holes CC positioned inside the insulating film 90 are not filled with the insulating film 22F because the diameters are larger than a value 2 times the film thickness of the insulating film 22F. As a result, a recess is formed in the upper surface of the insulating film 22F. For example, the insulating film 22F is formed using an insulating material such as silicon oxide, etc. Subsequently, the mask material MS4 is removed.

As shown in FIG. 20A and FIG. 20B, a portion of the insulating film 22F is removed by performing isotropic etching via the holes CC. For example, an etchant such as hydrofluoric acid or the like is introduced via the holes CC. Thereby, the side surface of the insulating film 90 and the upper surface of the electrode layer 41 of the uppermost layer are exposed from the insulating film 22F inside the holes CC.

At this time, the insulating film 22F remains at the portions positioned lower than the electrode layer 41 of the uppermost layer inside the hole CC. The insulating film 22F that remains becomes the insulating portions 22. Thereby, the insulating portions 22 are formed inside the holes CC. When removing the portion of the insulating film 22F, for example, the side surface of the electrode layer 41 of the uppermost layer inside the hole CC also may be exposed from the insulating film 22F by also removing the insulating film 22F that is on the side surface of the electrode layer 41 of the uppermost layer.

The portion of the insulating film 22F may be removed by anisotropic etching such as RIE (reactive ion etching), etc. In such a case, the upper surface of the electrode layer 41 of the uppermost layer inside the hole CC is exposed from the insulating film 22F.

As shown in FIG. 5 and FIG. 6, the conductive portion 21 is formed on the insulating portion 22. The conductive portion 21 contacts the upper surface of the electrode layer 41. In the case where the side surface of the electrode layer 41 is exposed inside the hole CC, the conductive portion 21 also contacts the side surface of the electrode layer 41. Subsequently, the sacrificial member SM that is inside the hole CS (referring to FIG. 20A and FIG. 20B) is removed. The contact plug 71 is formed inside the hole CS. For example, the contact plug 71 is connected to the base material 10.

In the semiconductor device according to the embodiment, the contact portion 20 that includes the conductive portion 21 and the insulating portion 22 is provided. For example, the contact portion 20 performs both the role of a contact connecting the electrode layer 41 to the interconnect of the upper layer and the role of a post of the staircase structure portion 2. Thereby, for example, the number of posts provided in the staircase structure portion 2 can be reduced. For example, the surface area of the staircase structure portion 2 can be reduced.

In the semiconductor device according to the embodiment, the conductive portion 21 is connected to the upper surface of the electrode layer 41 and the inner surface of the hole CC formed in the electrode layer 41. Thereby, the connection surface area between the conductive portion 21 and the electrode layer 41 can be increased.

In the method for manufacturing the semiconductor device according to the embodiment, the sacrificial member SM that is inside the holes CC functions as posts supporting the staircase structure portion 2 in the replace process. The sacrificial member SM that is inside the holes CC is replaced in a subsequent process with the contact portions 20 that function as contacts between the electrode layers 41 and the interconnects of the upper layer. Thereby, the region for providing the contact portions of the staircase structure portion 2 also can be used as the region for providing the posts. Therefore, for example, the surface area of the staircase structure portion 2 can be reduced. Further, the number of posts can be reduced because the contact portions 20 (the sacrificial member SM) function as posts. Therefore, the processes for forming the posts can be reduced.

Another method for manufacturing the semiconductor device according to the embodiment will now be described.

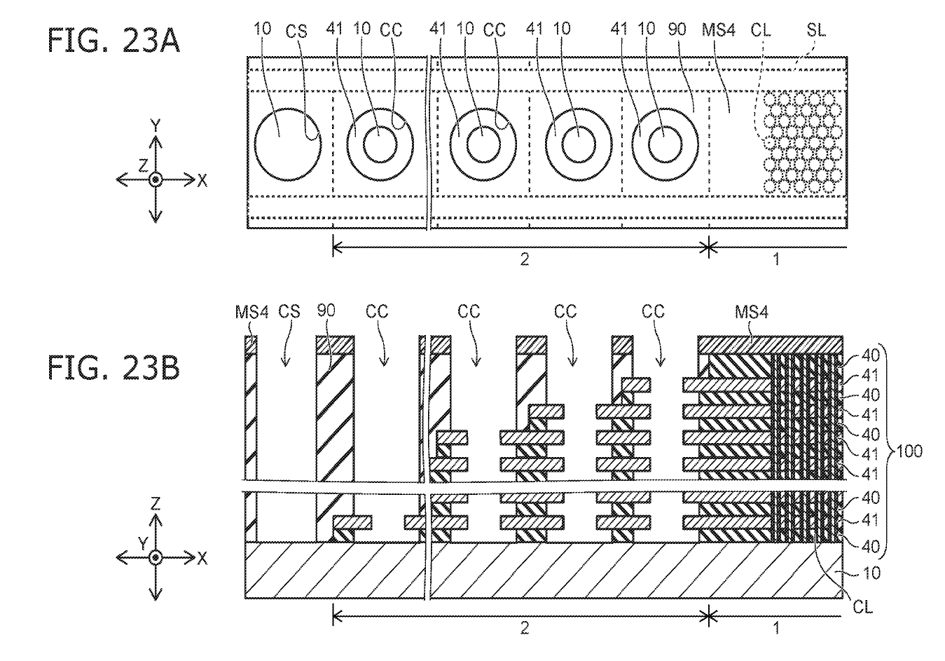

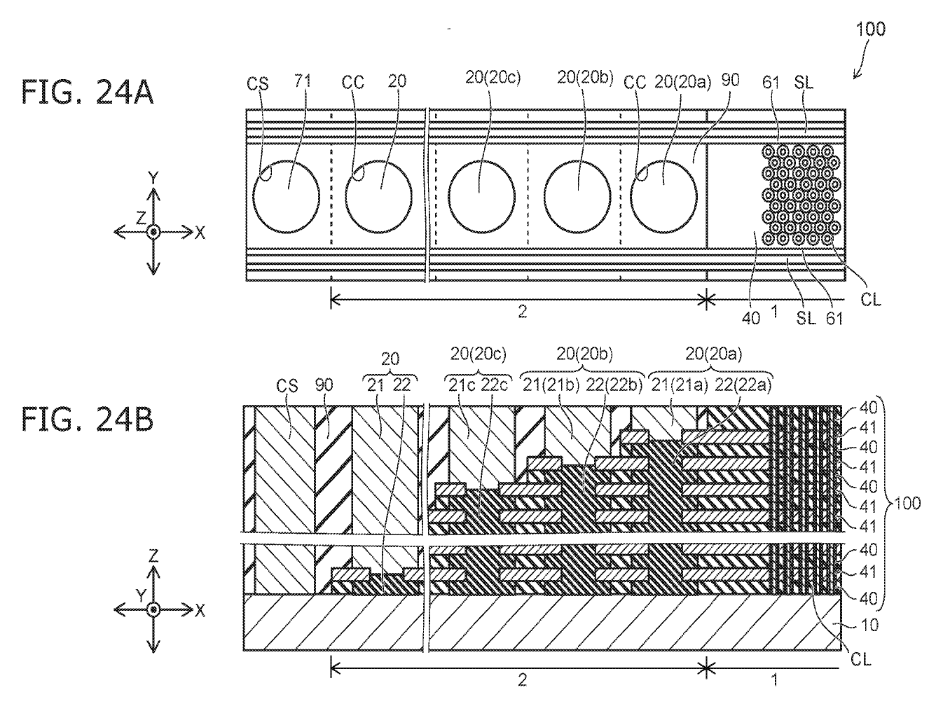

FIG. 23A to FIG. 24B are drawings showing the method for manufacturing the semiconductor device according to the embodiment. FIG. 23A and FIG. 24A correspond to the plan view shown in FIG. 5. FIG. 23B and FIG. 24B correspond to the cross-sectional view shown in FIG. 6.

First, the processes shown in FIG. 8A to FIG. 17B are implemented. Subsequently, the sacrificial member SM that is inside the hole CS and inside the holes CC (referring to FIG. 17A and FIG. 17B) is removed as shown in FIG. 23A and FIG. 23B. For example, the mask material MS4 is formed on the insulating film 90, on the stacked body 100, on the columnar portions CL, on the insulating films 61, and on the source layers SL. The upper surface of the sacrificial member SM is exposed from the mask material MS4. Subsequently, for example, anisotropic etching is performed. Thereby, the sacrificial member SM is removed.

Subsequently, isotropic etching such as wet etching or the like is performed. Thereby, the insulating film 90 and the insulating bodies 40 that are exposed at the inner surfaces of the holes CC are caused to recede. As a result, the diameters of the holes CC inside the insulating film 90 become large. Also, the diameters of the holes CC inside the insulating bodies 40 become large. Thereby, a portion of the upper surfaces of the electrode layers 41 inside the holes CC is exposed from the insulating film 90. Further, in the example, the side surface of the hole CS also recedes. Thereby, the diameter of the hole CS also is enlarged.

Processes that are similar to the processes shown in FIG. 19A to FIG. 20B are implemented. As shown in FIG. 24A and FIG. 24B, the conductive portions 21 are formed inside the holes CC. Thereby, the contact portions 20 that include the conductive portion 21 and the insulating portion 22 are formed inside the holes CC. Also, the contact plug 71 is formed inside the hole CS. By such a method as well, the semiconductor device according to the embodiment can be manufactured.

Thus, according to the embodiments, a semiconductor device can be obtained in which it is possible to reduce the planar size of the staircase structure portion.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

1. A semiconductor device, comprising:
a base material;
a plurality of electrode layers provided above the base material and alternately stacked with a plurality of insulating layers therebetween along a first direction;
an insulating film provided above the plurality of electrode layers and above the base material; and
a first contact portion extending through the insulating film and the plurality of electrode layers in the first direction,
the plurality of electrode layers including
a first electrode layer, and
a second electrode layer positioned between the base material and the first electrode layer,
the first contact portion including
a first conductive portion extending in the first direction, being electrically connected to the first electrode layer, and being insulated from the second electrode layer, a lower end of the first conductive portion being positioned lower than an upper surface of the first electrode layer, and
a first insulating portion extending through the second electrode layer and one of the plurality of insulating layers in the first direction and being provided between the base material and the first conductive portion, the one of the plurality of insulating layers being positioned between the first electrode layer and the second electrode layer, and
a first diameter of the first conductive portion positioned inside the insulating film being not less than a second diameter of the first insulating portion positioned inside the one of the plurality of insulating layers.

2. The device according to claim 1, wherein the first conductive portion contacts the upper surface of the first electrode layer.

3. The device according to claim 1, wherein
the first electrode layer includes a first end portion having a first hole,
the second electrode layer has a second hole, at least a portion of the second hole overlapping the first hole when viewed from the first direction,
the first conductive portion contacts the upper surface of the first electrode layer and an inner surface of the first hole, and
a portion of the first insulating portion is provided inside the second hole.

4. The device according to claim 3, wherein the first conductive portion contacts the upper surface of the first electrode layer in a region surrounding the first hole of the first end portion.

5. The device according to claim 1, wherein the lower end of the first conductive portion is positioned higher than an upper surface of the second electrode layer.

6. The device according to claim 1, further comprising a second contact portion extending in the first direction,
the plurality of electrode layers further including a third electrode layer positioned between the base material and the second electrode layer,
the second contact portion including:
a second conductive portion extending in the first direction, being electrically connected to the second electrode layer, and being insulated from the third electrode layer, a lower end of the second conductive portion being positioned lower than an upper surface of the second electrode layer; and
a second insulating portion extending through the third electrode layer in the first direction and being provided between the base material and the second conductive portion,
the second electrode layer including a second end portion not overlapping the first electrode layer when viewed from the first direction, the second end portion having a third hole, and
the second conductive portion contacting the upper surface of the second electrode layer in a region surrounding the third hole of the second end portion.

7. The device according to claim 6, wherein the second conductive portion also contacts an inner surface of the third hole.

8. The device according to claim 1, further comprising a columnar portion extending through the plurality of electrode layers in the first direction,
the columnar portion including:
a semiconductor film extending in the first direction; and
a memory portion provided between the semiconductor film and the plurality of electrode layers.

9. The device according to claim 8, wherein the semiconductor film is electrically connected to the base material.

10. A semiconductor device, comprising:
a base material;
a plurality of electrode layers alternately stacked with a plurality of insulating layers therebetween along a first direction above the base material, the plurality of electrode layers including a first electrode layer and a second electrode layer, the first electrode layer including a first end portion having a first hole, the second electrode layer being positioned between the base material and the first electrode layer; and
a first conductive portion extending in the first direction and being electrically connected to the first electrode layer,
the first conductive portion being connected to the first electrode layer at an inner surface of the first hole and in a region surrounding the first hole of the first end portion on the first electrode layer, a lower end of the first conductive portion being positioned higher than an upper surface of the second electrode layer,
one of the plurality of insulating layers being positioned between the first electrode layer and the second electrode layer, the one of the plurality of insulating layers having a hole, at least a portion of the hole overlapping the first hole when viewed from the first direction, and
a first diameter of the first conductive portion positioned on the first electrode layer being not less than a second diameter of the hole of the one of the plurality of insulating layers.

11. The device according to claim 10, wherein the second electrode layer has a second hole, at least a portion of the second hole overlapping the first hole when viewed from the first direction.

12. The device according to claim 11, further comprising a first insulating portion extending in the first direction, being disposed between the base material and the first conductive portion, and contacting the first conductive portion.

13. The device according to claim 12, wherein a portion of the first insulating portion is positioned inside the second hole.

14. The device according to claim 10, further comprising a second conductive portion extending in the first direction and being electrically connected to the second electrode layer,
the plurality of electrode layers further including a third electrode layer positioned between the base material and the second electrode layer,
the second electrode layer including a second end portion not overlapping the first electrode layer when viewed from the first direction, the second end portion having a third hole, and
the second conductive portion being connected to the second electrode layer at an inner surface of the third hole and in a region surrounding the third hole of the second end portion, a lower end of the second conductive portion being positioned higher than an upper surface of the third electrode layer.

15. The device according to claim 10, further comprising a columnar portion extending through the plurality of electrode layers in a first direction,
the columnar portion including:
a semiconductor film extending in the first direction and being electrically connected to the base material; and
a memory portion provided between the semiconductor film and the plurality of electrode layers.

16. A method for manufacturing a semiconductor device, comprising:
forming a stacked body including a plurality of first layers and a plurality of second layers stacked alternately along a first direction, the plurality of second layers being made of a material different from the plurality of first layers;
forming a staircase structure portion in an end portion of the stacked body, the staircase structure portion having a terrace formed in each of the plurality of first layers;
forming an insulating film on the staircase structure portion;
forming a hole extending in the first direction through the insulating film and through the staircase structure portion;
forming a first member inside the hole;
replacing the plurality of first layers with a plurality of electrode layers in the stacked body having the first member formed in the staircase structure portion;
removing the first member;
forming an insulating portion at a lower portion inside the hole where the first member is removed; and
forming a conductive portion at an upper portion inside the hole, the conductive portion being connected to the electrode layer of the uppermost layer of the plurality of electrode layers exposed at an inner surface of the hole.

17. The method according to claim 16, further comprising:
after the removing of the first member, causing the insulating film exposed at a side surface of the hole to recede.

18. The method according to claim 16, wherein the conductive portion contacts an upper surface of the electrode layer of the uppermost layer.

19. The method according to claim 18, wherein the conductive portion also contacts a side surface of the electrode layer of the uppermost layer.

20. The method according to claim 16, further comprising, prior to the replacing of the plurality of first layers with the plurality of electrode layers in the stacked body:
forming a memory hole extending through the stacked body in the first direction;
forming a memory portion inside the memory hole; and
forming a semiconductor film inside the memory hole with the memory portion interposed.
